(19) United States
(12) Patent Application Publication
(10) Pub. No.: US 2008/0185587 A1
(43) Pub. Date: Aug. 7, 2008

(54) DISPLAY PANEL AND METHOD OF MANUFACTURE

(76) Inventors: Sang-Woo Whangbo, Seoul (KR); Jun-Hyung Souk, Yongin-si (KR); Yong-Suk Jin, Yongin-si (KR); Jin-Ho Ju, Seoul (KR); Min Kang, Seoul (KR); Myo-Kyong Joo, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/928,697

(22) Filed: Oct. 30, 2007

(30) Foreign Application Priority Data
Feb. 5, 2007 (KR) 10-2007-0011496

(51) Int. Cl. H01L 29/04; H01L 21/336

(52) U.S. Cl. 257/59; 438/158; 257/E29.003; 257/E21.414

(57) ABSTRACT

A display panel and a manufacturing method in which the display panel includes an alkali-containing glass substrate having a surface waviness of less about 0.06 μm, a gate electrode formed the substrate, a gate insulating layer formed on the gate electrode, a semiconductor formed on the gate insulating layer, a source electrode and a drain electrode contacting the semiconductor, and a pixel electrode electrically connected to the drain electrode.

### CROSS-REFERENCE TO RELATED APPLICATION

This application claims priority to and the benefit of Korean Patent Application No. 10-2007-0011496 filed in the Korean Intellectual Property Office on Feb. 5, 2007, the entire contents of which are incorporated herein by reference.

### BACKGROUND OF THE INVENTION

1. Field of the Invention

The present invention relates to a display panel and a manufacturing method thereof.

2. Description of the Related Art

A liquid crystal display (LCD) includes two display panels having field-generating electrodes and a liquid crystal layer interposed between the two panels. A voltage is applied to the electrodes to realign liquid crystal molecules of the liquid crystal layer and thereby control the transmittance of light passing through the liquid crystal layer. A plurality of pixel electrodes are arranged in a matrix format in one display panel (hereinafter referred to as a “thin film transistor array panel”) and one common electrode covers the entire surface of the other display panel (hereinafter referred to as a “common electrode panel”). In such an LCD, an additional voltage is applied to each pixel electrode to perform image display. Thin film transistors (TFTs) apply data voltages to the pixel electrodes under the control of switching signals applied over gate lines to gate electrodes of the transistors.

The display panel includes an insulating substrate and a plurality of thin films formed thereon. The insulating substrate may be made of a transparent material such as glass, which may be an alkali- or a non-alkali-containing glass that melts at a high temperature of about 1700° C., the lateral sides of the glass being cooled by air. When the substrate is manufactured by a fusion method, the manufacturing cost is high. On the other hand, since an alkali-containing glass substrate can be manufactured at a relatively low melting temperature, the manufacturing cost can be reduced compared to the non-alkali-containing glass substrate. However, the alkali-containing glass substrate is manufactured by using a floating method and thus one side of the substrate is cooled by air and the other side is cooled by liquid which may cause the substrate to have protrusions and depressions on its surface according to the transfer direction. These protrusions and depressions cause the display to appear blurred. In addition, an alkali component contained in the alkali-containing substrate may be melted during the follow-up processes, thereby affecting stability of elements.

### SUMMARY OF THE INVENTION

An exemplary display panel according to one embodiment of the present invention having improved flatness includes an alkali-containing glass substrate, a gate electrode, a gate insulating layer, a semiconductor, a source electrode, a drain electrode, and a pixel electrode. The alkali-containing glass substrate has surface waviness of less than about 0.06 μm. The gate electrode is formed on the substrate, the gate insulating layer is formed on the gate electrode, a semiconductor layer is formed on the gate insulating layer, source and drain electrodes are formed to contact the semiconductor, and the pixel electrode is electrically connected to the drain electrode.

The alkali-containing glass substrate may have a surface roughness of less than about 20 Å.

The gate insulating layer may include silicon nitride (SiNx), and may have a thickness between about 500 Å to 4500 Å.

The gate insulating layer may include a first gate insulating layer and a second gate insulating layer, each having a different deposition density.

The alkali-containing glass substrate may be a soda lime glass substrate.

An exemplary display panel according to another exemplary embodiment of the present invention includes an alkali-containing glass substrate, a gate electrode, a gate insulating layer, a semiconductor, source and drain electrodes, a pixel electrode, and a color filter. The alkali-containing glass substrate has a surface waviness of less than about 0.06 μm. The gate electrode is formed on the substrate, the gate insulating layer is formed on the gate electrode, the semiconductor is formed on the gate insulating layer, the source and drain electrodes contact the semiconductor, the pixel electrode is connected to the drain electrode and includes a plurality of cutouts, and the color filter is disposed between the substrate and the pixel electrode.

The color filter may be disposed between the source electrode, the drain electrode, and the pixel electrode, and may further include an inorganic insulating layer interposed between the color filter and the pixel electrode.

The color filter may be disposed between the substrate and the gate electrode, and may further include a planarization layer interposed between the color filter and the gate electrode.

The display panel may further include a light blocking member disposed in a lower portion of the color filter.

The display panel may further include a light blocking member disposed in an upper portion of the semiconductor.

An exemplary manufacturing method of a display panel according to one embodiment of the present invention includes: preparing an alkali-containing glass substrate having a surface waviness of less than 0.06 μm; forming a gate electrode on the substrate; substantially forming a gate insulating layer and a semiconductor on the gate electrode; forming a source electrode and a drain electrode on the gate insulating layer and the semiconductor; and forming a pixel electrode connected to the drain electrode.

The preparing of the alkali-containing glass substrate may include polishing a surface of the substrate.

The preparing of the alkali-containing glass substrate may include forming a planarization layer on the substrate.

The gate insulating layer and the semiconductor may be formed by deposition at temperature of less than 250° C.

The forming of the gate insulating layer may include forming a first gate insulating layer, and forming a second gate insulating layer with a deposition condition that is different from a deposition condition of the first gate insulating layer to make the first gate insulating layer and the second gate insulating layer have different densities.

The manufacturing method may further include performing an annealing process on the substrate before the preparing of the alkali-containing glass substrate.

The annealing process may be performed on the substrate by using a convection oven at a temperature between 150 to 400° C. or may be performed by placing the substrate in a furnace.

Before the forming of the pixel electrode, the manufacturing method may further include forming a color filter after forming the source electrode and the drain electrode, and forming an inorganic insulating layer on the color filter.

Before the forming of the gate electrode, the manufacturing method may further include forming a color filter on the substrate, and forming a planarization layer on the color filter.

An exemplary manufacturing method of a display panel according to another embodiment of the present invention includes: performing an annealing process on an alkali-containing glass substrate; polishing the alkali-containing glass substrate on the substrate to make surface waviness of the substrate less than 0.06 μm; forming a gate electrode on the substrate; substantially forming a gate insulating layer and a semiconductor at a temperature of less than 250° C. after forming the gate electrode; forming a source electrode and a drain electrode after forming the gate insulating layer and the semiconductor; and forming a pixel electrode connected to the drain electrode.

An exemplary manufacturing method of a display panel according to another embodiment of the present invention includes: performing an annealing process on an alkali-containing glass substrate; forming a planarization layer to make a surface waviness of the substrate less than 0.06 μm; forming a gate electrode on the substrate; substantially forming a gate insulating layer and a semiconductor at a temperature of less than 250° C. after forming the gate electrode; forming a source electrode and a drain electrode after forming the gate insulating layer and the semiconductor; and forming a pixel electrode connected to the drain electrode.

### BRIEF DESCRIPTION OF THE DRAWINGS

FIG. 1 is a layout view of a thin film transistor (TFT) array panel for a liquid crystal display (LCD) according to an exemplary embodiment of the present invention.

FIG. 2 is a layout view of a common electrode panel for the LCD according to the exemplary embodiment of the present invention.

FIG. 3 is a layout view of an LCD that includes the TFT array panel of FIG. 1 and the common electrode panel of FIG. 2.

FIG. 4 is a cross-sectional view of the LCD of FIG. 3, taken along line IV-IV.

FIG. 5 is a cross-sectional view of the LCD of FIG. 3 according to another exemplary embodiment of the present invention, taken along line IV-IV.

FIG. 6 is a cross-sectional view of the LCD of FIG. 3 according to still another exemplary embodiment of the present invention, taken along line IV-IV.

FIG. 7 is a layout view of an LCD according to another exemplary embodiment of the present invention.

FIG. 8 is a cross-sectional view of the LCD of FIG. 7, taken along line VIII-VIII.

FIG. 9A is a histogram showing variation in the length of a substrate after a thin film is formed in accordance with a pre-compaction process.

FIG. 9B is a histogram showing variation of the length of a substrate after a thin film is formed in accordance with a convention method.

### DETAILED DESCRIPTION OF THE EMBODIMENTS

The present invention will be described more fully hereinafter with reference to the accompanying drawings, in which exemplary embodiments of the invention are shown.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

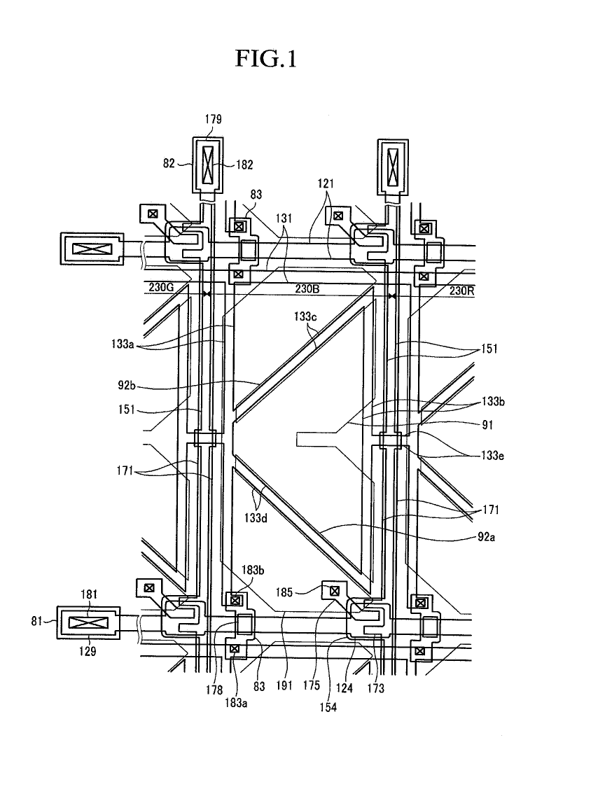

A liquid crystal display (LCD) according to an exemplary embodiment of the present invention will be described in further detail with reference to FIG. 1 to FIG. 5.

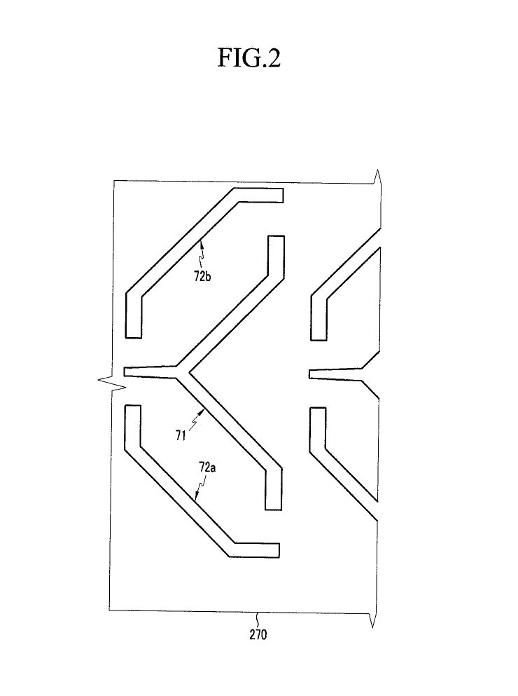

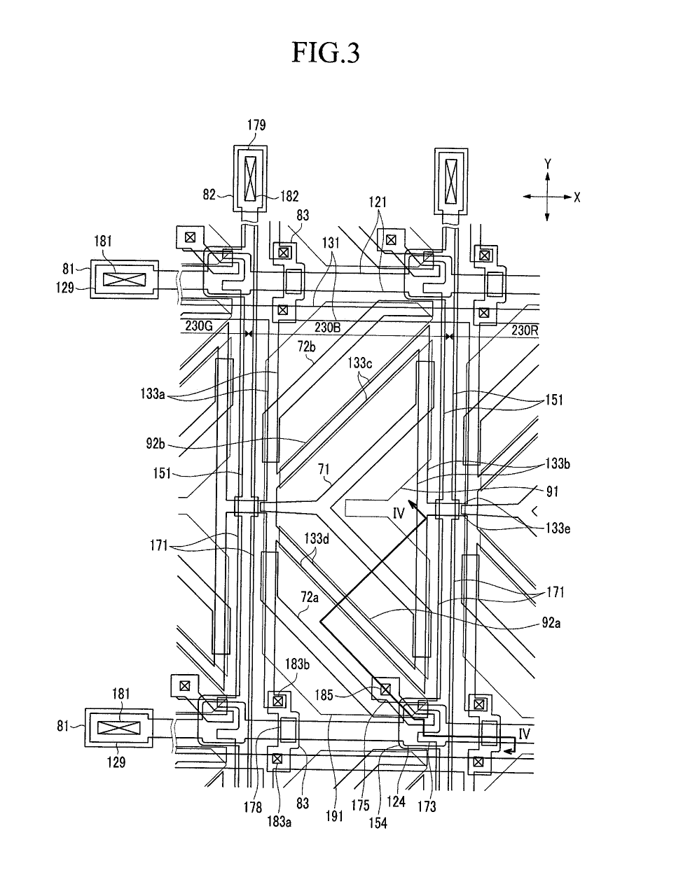

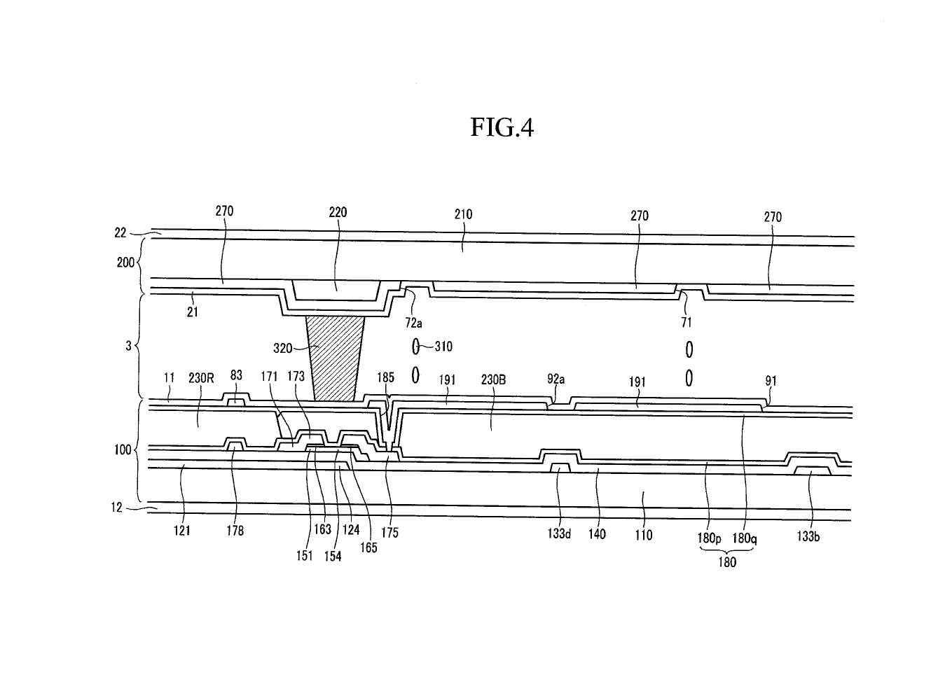

FIG. 1 is a layout view of a thin film transistor (TFT) array panel for an LCD according to an exemplary embodiment of the present invention, FIG. 2 is a layout view of a common electrode array panel for an LCD according to the exemplary embodiment of the present invention, FIG. 3 is a layout view of an LCD including the TFT array panel of FIG. 1 and the common electrode array panel of FIG. 2, and FIG. 4 is a cross-sectional view of the LCD of FIG. 3, taken along line IV-IV.

Referring to FIG. 1 to FIG. 4, the LCD according to the exemplary embodiment of the present invention includes a TFT array panel 100, a common electrode display panel 200, and a liquid crystal layer 3. The TFT array panel 100 and the common electrode display panel 200 face each other, and the liquid crystal layer 3 is interposed between the two panels 100 and 200.

The TFT array panel 100 will now be described with reference to FIG. 1, FIG. 3, and FIG. 4.

The TFT array panel 100 includes a transparent insulating substrate 110 and a plurality of thin films formed on the insulating substrate 110.

The insulating substrate 110 may be made of soda lime glass containing an alkali component such as Na₂O, CaO, and MgO.

Since the soda lime glass can be manufactured at a relatively low melting temperature as in a floating process, the soda lime glass is advantageous in terms of manufacturing cost. However, a block dot and/or line-shaped display blur may be observed in a display panel made of the soda lime glass.

In order to find a cause of the display blur observed in the soda lime glass substrate, the present invention determined occurrence of blurs while changing surface waviness of the soda lime glass substrate. Herein, the surface waviness indicates a degree of roughness of a surface. That is, the surface waviness represents a degree to which roughness repeatedly showing on a surface is out of an ideal surface, and it is represented by a numerical value wherein a high value indicates that the roughness of the surface is severe and a low value indicates that the roughness of the surface is more uniform.

It has been determined that external blur is not observed when the average surface waviness of the soda lime glass substrate is less than about 0.06 μm as shown in Table 1 (2 cm scanning basis).

TABLE 1

| Surface waviness (μm) | Display blur observation |
|---|---|
| 0.20 | ◯ |
| 0.12 | ◯ |
| 0.10 | ◯ |
| 0.06 | X |

In a test, the degree of a roughness indicated by a numerical value varied within a narrower range showing that a display blur is not observed when surface roughness is less than about 20 for every 2 mm scanning interval. Surface roughness can be measured by scanning an atomic force microscope (AFM) along the substrate in one direction.

The display blurs observed in a soda lime glass substrate can be reduced by controlling the soda lime glass to have less surface waviness and surface roughness than predetermined levels, for example, a surface waviness of less than 0.06 μm and a surface roughness of less than 20 Å. A plurality of gate lines 121 and a plurality of storage electrode lines 131 are formed on the insulating substrate 110 made of the soda lime glass.

The gate lines 121 transmit gate signals, and extend in a horizontal direction. Each gate line 121 includes a plurality of gate electrodes 124 that protrude upward and a wide end portion 129 for connecting to another layer or an external driving circuit. A gate driving circuit (not shown) that generates gate signals may be mounted on a flexible printed circuit film (not shown) that is attached to the substrate 110, it may be directly mounted on the substrate 110, or it may be integrated with the substrate 110. When the gate driving circuit is integrated with the substrate 110, the gate lines 121 may be extended to be directly connected thereto.

The storage electrode lines 131 receive a predetermined voltage, and include stem lines extending substantially in parallel with the gate lines 121, a plurality of first, second, third, and fourth storage electrode sets 133a, 133b, 133c, and 133d that branch off from the stem lines, and a plurality of connection units 133e. Each of the storage electrode lines 131 is disposed between two adjacent gate lines 121, and its respective stem line is arranged closer to the upper one of the two adjacent gate lines 121.

The first and second storage electrodes 133a and 133b extend in a vertical direction and face each other. The first storage electrode 133a includes a fixed end connected to the stem line and a free end opposite to the fixed end, whereby the free end has a projection. The third and fourth storage electrodes 133c and 133d extend obliquely from the center of the first storage electrode 133a to the lower and upper ends of the second storage electrode 133b. The connection units 133e are connected between adjacent sets of the storage electrodes 133a to 133d. The shape and disposition of the storage electrode lines 131 may be variously changed.

The gate lines 121 and the storage electrode lines 131 may be made of a conductor having a low resistance, for example an aluminum-based metal such as aluminum (Al) or an Al alloy, a silver-based metal such as silver (Ag) or a Ag alloy, a copper-based metal such as copper (Cu) or a Cu alloy, a molybdenum-based metal such as molybdenum (Mo) or a Mo alloy, chromium (Cr), tantalum (Ta), or titanium (Ti). The gate lines 121 and the storage electrode lines 131 may have a multilayer structure including two conductive layers (not shown) that have different physical properties from each other.

The sides of the gate lines 121 and the storage electrode lines 131 incline toward the surface of the substrate 110 at an angle of about 30 degrees to about 80 degrees.

A gate insulating layer 140 is formed on the gate lines 121 and storage electrode lines 131.

The gate insulating layer 140 may be made of silicon nitride (SiNₓ) or silicon oxide (SiOₓ), and may have a thickness of about 1000 to 4500 Å. Since the gate insulating layer 140 blocks an alkali component output from the insulating substrate 110 that is made of the soda lime glass, an additional blocking film for blocking the output of the alkali component is not needed.

The gate insulating layer 140 may include two layers having different film quality from each other, and the upper gate insulating layer (not shown) may have superior film quality since it is formed with a density that is higher than that of the lower gate insulating layer. For example, when the thickness of the gate insulating layer 140 is about 4500 Å, the thickness of the upper gate insulating layer is about 5000 Å and that of the lower gate insulating layer is about 4000 Å.

On the gate insulating layer 140, a plurality of semiconductor stripes 151 that are made of hydrogenated amorphous silicon (abbreviated as a-Si) or polysilicon are formed. The semiconductor stripes 151 extend mainly in a vertical direction and have a plurality of projections 154 that protrude toward the gate electrodes 124.

A plurality of ohmic contact stripes, each having a projection 163, and a plurality of ohmic contact islands 165 are formed on the semiconductor stripes 151. The ohmic contacts 163 and 165 may be made of a material such as n+ hydrogenated a-Si that is heavily doped with an n-type impurity, or of silicide. A pair of a projection and an ohmic contact island 165 is disposed on each projection 154 of the semiconductor stripes 151.

The sides of the semiconductor stripes 151 and the ohmic contacts 163 and 165 are also inclined toward the surface of the substrate 110 at an angle of about 30 degrees to about 80 degrees.

A plurality of data lines 171, a plurality of drain electrodes 175, and a plurality of isolated metal pieces 178 are formed on the ohmic contacts 163 and 165 and the gate insulating layer 140.

Each data line 171 transmits a data signal, and extends in a vertical direction to cross the gate lines 121, the stem lines of the storage electrode lines 131, and the connections 133e. Each data line 171 includes a plurality of source electrodes 173 extending toward the gate electrodes 124 and a wide end portion 179 for connecting to another layer or an external driving circuit. A data driving circuit (not shown) for generating a data voltage may be mounted on the flexible printed circuit film (not shown) attached to the substrate 110 or directly mounted on the substrate 110, or may be integrated with the substrate 110. If the data driving circuit is integrated with the substrate 110, the data lines 171 may extend to be directly connected to the data driving circuit.

The drain electrodes 175 are separated from the data lines 171 and face the source electrodes 173, centering the gate electrodes 124. Each drain electrode 175 has one wide end portion and another rod-shaped end portion, whereby the rod-shaped end portion may be partially surrounded by the source electrode 173.

A gate electrode 124, a source electrode 173, and a drain electrode 175 form a thin film transistor (TFT) together with the projection 154 of the semiconductor stripe 151, and a channel of the TFT is formed in the projection 154 between the source electrode 173 and the drain electrode 175.

The isolated metal pieces 178 are disposed on the gate lines 121 around the first storage electrode 133a.

The data lines 171, the drain electrodes 175, and the isolated metal pieces 178, like the gate lines 121, may also be made of a low resistive conductor.

The sides of the data lines 171, the drain electrodes 175, and the isolated metal pieces 178 are also inclined toward the surface of the substrate 110 at an angle of about 30 degrees to about 80 degrees.

The ohmic contacts 163 and 165 exist only between the below semiconductor stripes 151 and the above data lines 171 and drain electrodes 175 to reduce the contact resistance between them.

A passivation layer 180p is formed on the data lines 171, the drain electrodes 175, the isolated metal pieces 178, and exposed portions of the semiconductor stripes 151. The passivation layer 180p may be made of an inorganic insulating material such as silicon nitride or silicon oxide.

On the passivation layer 180p, color filters 230R and 230B are formed. Herein, the color filter 230R refers to a red filter and the color filter 230B refers to a blue filter. The red filter 230R, a green filter (not shown in FIG. 4), and the blue filter 230B may be extended in parallel with pixel rows that are partitioned by the data lines, or they may be alternately formed on the pixel rows.

On the color filters 230R and 230B, a capping layer 180q is formed. The capping layer 180q may be made of an inorganic material such as silicon nitride, and it blocks outgassing from the color filters 230R and 230B to thereby reduce a residual image.

On the capping layer 180q, a plurality of pixel electrodes 191, a plurality of overpasses 83, and a plurality of contact assistants 81 and 82 are formed. They may be made of a transparent conductive material such as ITO or IZO, or a reflective metal such as aluminum, silver, chromium, or an alloy thereof.

Each pixel electrode 191 is physically and electrically connected to a drain electrode 175 through a contact hole 185 and receives a data voltage from the drain electrode 175. Each pixel electrode 191 to which the data voltage is applied generates an electric field together with a common electrode 270 of the common electrode display panel 200 to which a common voltage is applied to determine the direction of liquid crystal molecules in the liquid crystal layer 3 between the pixel electrode 191 and the common electrode 270. Polarization of light passing through the liquid crystal layer varies depending on the determined direction of the liquid crystal molecules. The pixel electrodes 191 and the common electrode 270 form capacitors (hereinafter referred to as liquid crystal capacitors) to sustain the applied voltage even after the TFTs are turned off.

The pixel electrodes 191 overlap with the storage electrodes 133a to 133d and the storage electrode lines 131. Capacitors formed by overlapping the pixel electrodes 191 and the drain electrodes 175, which are electrically connected to the pixel electrodes 191, with the storage electrode lines 131 are called storage capacitors, and the storage capacitors enhance the voltage sustaining ability of the liquid crystal capacitors.

Each pixel electrode 191 has four main sides that run substantially parallel to the gate lines 121 or the data lines 171, and may have a quadrangle shape including four chamfered corners. The chamfered sides of the pixel electrodes 191 make an angle of about 45 degrees with the gate lines 121. A central cutout 91, a lower cutout 92a, and an upper cutout 92b are formed on each pixel electrode 191, and the pixel electrode 191 is divided into a plurality of partitions by these cutouts 91, 92a, and 92b. The cutouts 91 to 92b are almost inversely symmetrical with a virtual horizontal central line that halves the pixel electrode 191.

The lower and upper cutouts 92a and 92b extend obliquely from the right side of the pixel electrode 191 to the left side, and overlap with the third and fourth storage electrodes 133c and 133d, respectively. The lower and upper cutouts 92a and 92b are placed at lower and upper regions with respect to the horizontal central line of the pixel electrode 191, respectively. The lower and upper cutouts 92a and 92b make an angle of about 45 degrees with the gate lines 121 and extend perpendicularly to one another.

The central cutout 91 extends along the horizontal central line of the pixel electrode 191 and has an entrance at the right side. The entrance of the central cutout 91 has a pair of oblique sides each parallel to the lower cutout 92a and the upper cutout 92b. The central cutout 91 includes a horizontal section and a pair of oblique sections connected to the horizontal section. The horizontal section extends shortly along the horizontal central line of the pixel electrode 191, and the pair of oblique sections extend from the horizontal section to the right side of the pixel electrode 191 to run parallel to the lower cutout 92a and the upper cutout 92b, respectively.

Therefore, the lower section of the pixel electrode 191 is divided into two regions by the lower cutout 92a, and the upper section of the pixel electrode 191 is divided into two regions by the upper cutout 92b. Here, the number of regions or cutouts may vary with design factors such as the size of the pixel electrode 191, the length ratio of the horizontal and vertical sides of the pixel electrode 191, and the characteristics of the liquid crystal layer 3.

The overpasses 83 are laid across the gate lines 121 and connected to the exposed portions of the storage electrode lines and the exposed free ends of the first storage electrodes 133a through contact holes 183a and 183b disposed on opposite sides of the gate lines 121. The storage electrodes 133a and 133b and the storage electrode lines 131 may be used together with the overpasses 83 to correct defects of the gate lines 121, the data lines 171, or the TFTs.

The contact assistants 81 and 82 are connected to the end portion 129 of the gate lines 121 and the end portion 179 of the data line 171 through contact holes 181 and 182, respectively. The contact assistants 81 and 82 supplement the connectivity of the end portion 129 of the gate line 121 and the end portion 179 of the data line 171 with external devices, and protect them.

The common electrode panel 200 will now be described in further detail with reference to FIG. 2 to FIG. 4.

The common electrode panel 200 has a structure in which a plurality of thin films are formed on a transparent insulating substrate 210.

The insulating substrate 210 is made of soda lime glass that contains an alkali component such as Na₂O, CaO, and MgO. As described above, the insulating substrate 210 has a surface waviness of less than 0.06 μm and a surface roughness of less than 20 Å.

On the insulating substrate 210 made of the soda lime glass, a light blocking member 220 is formed. The light blocking member 220 is also called a black matrix and prevents light leakage from between the pixel electrodes 191.

A common electrode 270 is formed on the substrate 210 and the light blocking member 220. The common electrode 270 may be made of a transparent conductor such as ITO and IZO, and a plurality of cutouts 71, 72a, and 72b are formed in the common electrode 270.

One set of cutouts 71 to 72b faces one pixel electrode 191 and includes a central cutout 71, a lower cutout 72a, and an upper cutout 72b. Each of the cutouts 71 to 72b is disposed between the adjacent cutouts 91 to 92b of the between the cutouts 92a and 92b and the chamfered sides of the pixel electrode 191. Each cutout 71 to 72b includes at least one oblique section extending to run parallel to the lower cutout 92a or the upper cutout 92b of the pixel electrode 191. The cutouts 71 to 72b are almost inversely symmetrical with respect to the horizontal central line of the pixel electrode 191.

The lower and upper cutouts 72a and 72b respectively include an oblique section, a horizontal section, and a vertical section. The oblique section extends basically from the upper or lower side of the pixel electrode 191 to the left side. The horizontal and vertical sections extend along the sides of the pixel electrode 191 to overlap with the sides and make an obtuse angle with the oblique section.

The central cutout 71 includes a central horizontal section, a pair of oblique sections, and a pair of end vertical sections. The central horizontal section extends basically from the left side of the pixel electrode 191 to the right along the horizontal central line of the pixel electrode 191. The pair of oblique sections extend from the end of the central horizontal section to the right side of the pixel electrode 191 to make an obtuse angle with the central horizontal section and run parallel to the lower and upper cutouts 72a and 72b, respectively. The end vertical section extends from the end of the corresponding oblique section to the right along the right side of the pixel electrode 191 to overlap with the right side and makes an obtuse angle with the corresponding oblique section.

The number of cutouts 71 to 72b may vary with the design factors. The light blocking member 220 overlaps with the cutouts 71 to 72b to block light leakage around the cutouts 71 to 72b.

Applying a common voltage to the common electrode 270 and a data voltage to the pixel electrode 191 generates an electric field that is almost vertical to the surface of the display panels 100 and 200. In response to the electric field, liquid crystal molecules tend to change the direction of their major axes to be vertical to the direction of the electric field.

The cutouts 71 to 72b and 91 to 92b of the field generating electrodes 191 and 270 and the sides of the pixel electrode make a horizontal component that changes the electric field to determine the inclined direction of the liquid crystal molecules. The horizontal component of the electric field is almost vertical to the sides of the cutouts 71 to 72b and 91 to 92b and the pixel electrode 191.

Referring to FIG. 3, one set of cutouts 71 to 72b and 91 to 92b divides the pixel electrode 191 into a plurality of sub-areas, and each sub-area has two primary edges that make an oblique angle with the primary sides of the pixel electrode 191. The primary sides of each sub-area make an angle of about 45 degrees with the polarization axis of polarizers 12 and 22 in order to maximize light efficiency.

Most of the liquid crystal molecules on the sub-areas incline in a direction vertical to the primary edges. There are approximately four inclined directions. When the inclined directions of the liquid crystal molecules are diversified, a reference viewing angle of the LCD becomes larger.

The shape and disposition of the cutouts 71 to 72b and 91 to 92b may be variously changed.

At least one of the cutouts 71 to 72b and 91 to 92b may be replaced with a protrusion (not shown) or depression (not shown). The protrusion may be made of an organic material or an inorganic material and be disposed above or below the field generating electrodes 191 and 270.

Alignment layers 11 and 21 are coated on an inner surface of the display panels 100 and 200 and may be vertical alignment layers.

The polarizers 12 and 22 are provided on outer surfaces of the display panels 100 and 200, and their polarization axes (X, Y) are perpendicular to each other and preferably make an angle of about 45 degrees with the oblique sections of the cutouts 92a, 92b, and 71 to 72b. In the case of a reflective LCD, one of the two polarizers 12 and 22 may be omitted.

The LCD according to the exemplary embodiment of the present invention may further include a phase retardation film (not shown) for compensating for the delay of the liquid crystal layer 3. Also, the LCD may further include a backlight unit (not shown) for providing the polarizers 12 and 22, the phase retardation film, the display panels 100 and 200, and the liquid crystal layer 3 with light.

A column spacer 320 is interposed between the display panels 100 and 200 for supporting them. The column spacer 320 may be placed to correspond to a thin film transistor portion, the gate line 121, and/or the data line 171, and may be made of an organic material that does not affect a liquid crystal material.

The liquid crystal layer 3 is in a state of negative dielectric anisotropy, and liquid crystal molecules 310 in the liquid crystal layer 3 are aligned such that their long axes are substantially vertical to the surfaces of the display panels 100 and 200 when no electric field is generated. Therefore, the incident light into the liquid crystal layer 3 cannot pass through the crossed polarizers 12 and 22, and is blocked.

A manufacturing method of the LCD according to the exemplary embodiment of the present invention will be described with reference to FIG. 1, FIG. 2, and FIG. 4.

### Preparation of Substrates 110 and 2100f Soda Lime Glass.

Since the soda lime glass has a high heat expansion coefficient, pre-compaction process is performed in order to stabilize the thermodynamic state of the soda lime glass before forming a thin film. The pre-compaction process expands or contracts the substrates 110 and 210 by performing an annealing process in advance before starting a thin film forming process with a high temperature. The pre-compaction process can reduce expansion or contraction of the soda lime glass substrate during the thin film forming process, thereby reducing misalignment during the thin film forming process.

The annealing process can be performed by the following two methods.

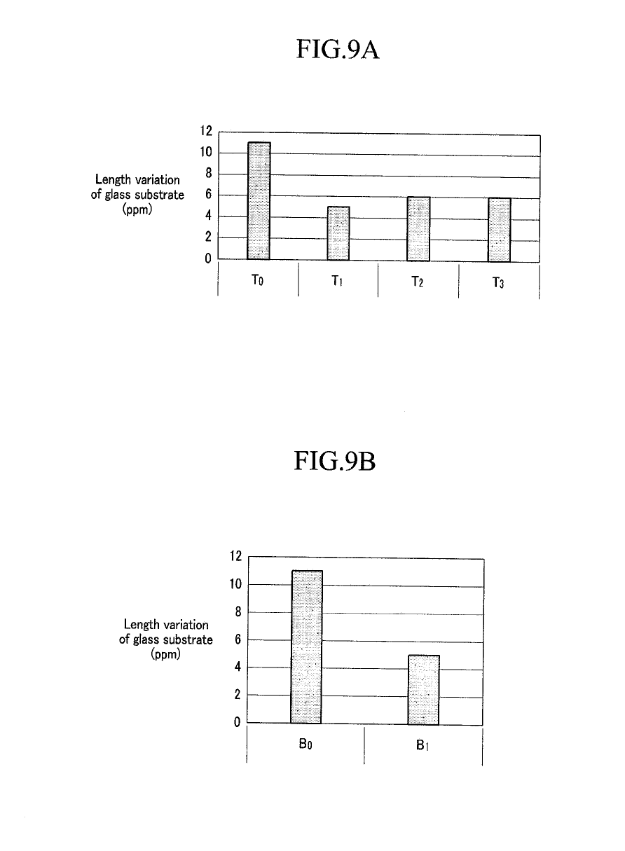

One is by placing the substrate in a high temperature furnace and performing the annealing process. In this case, the temperature of the furnace is preferably maintained at about 400° C., about 450° C., and about 500° C. for about 40 minutes, respectively. FIG. 9A is a histogram showing variation in the length of a substrate after a thin film is formed in accordance with a pre-compaction process. As shown in FIG. 9A, in the case that the pre-compaction process is not performed (T₀), a variation amount of the length of the substrate after the thin film is formed is about 11 ppm, and after the pre-compaction process substantially performed at about 400° C. (T₁), at about 450° C. (T₂), and at about 500° C. (T₃), the variation amount of the length of the substrate is significantly reduced to about 5-6 ppm.

The other method is placing the substrate in a convection oven and performing an annealing process with convection by using a hot air fan. In this case, the oven temperature can be maintained at about 150 to 400° C. for about 30 minutes to 12 hours, and for example, it is preferable to be maintained at about 220° C. for 2 hours. FIG. 9B is a histogram showing variation of the length of a substrate after a thin film is formed in accordance with a convention method. As shown in FIG. 9B, in the case (B₀) that the annealing process is not performed, the length of the substrate is changed about 11 ppm after the thin film is formed, and in the case (B₁) that the annealing process is performed for 2 hours at about 220° C., the length of the substrate is changed about 5 ppm after the thin film is formed. That is, the length difference is significantly reduced in the case B₁.

The annealing process can prevent the soda lime glass insulating substrates 110 and 210 from being expanded or contracted even though the substrates 110 and 210 are exposed to high temperatures in the follow-up processes.

After performing the pre-compaction process on the substrates 110 and 210, the substrates 110 and 210 are planarized by polishing them. The substrates 110 and 210 are polished until surface waviness of each substrate becomes less than 0.6 μm and surface roughness of each substrate becomes less than 20 Å.

Instead of polishing the substrates 110 and 210, a surface having roughness of the insulating substrates 110 and 210 that are made of the soda lime glass can be covered by coating an overcoat (not shown) over the substrates.

Therefore, manufacturing cost can be reduced by using a substrate made of soda lime glass, and the substrate can be thermally stabilized and planarization of a surface of the substrate can be increased by using the pre-compaction process and the polarization process.

A plurality of thin films are formed on the substrates 110 and 210.

Now, a manufacturing method of the TFT array panel 100 will be described.

A conductor layer is formed on the substrate 110 by using a sputtering process and is then subjected to photolithography to form a plurality of gate lines 121 that include gate electrodes 124 and end portions 129, and a plurality of storage electrodes 131 that include first, second, third, and fourth storage electrode sets 133a, 133b, 133c, and 133d and a plurality of connections 133e.

Next, a gate insulating layer 140 that is made of silicon nitride, an intrinsic semiconductor layer, and a second semiconductor layer doped with an impurity are formed on the gate lines 121 and storage electrode lines 131 by using a plasma enhanced chemical vapor deposition (PECVD) method. Herein, a deposition temperature is less than about 250° C.

Herein, the gate insulating layer 140 may be formed as two layers by using different deposition conditions. That is, the upper gate insulating layer and the lower gate insulating layer may have different densities by 1 differentiating a deposition ratio of each substrate. In this case, tensile stress is formed in the upper gate insulating layer and compression stress is formed in the lower gate insulating layer so that overall stress can be compensated, thereby preventing peeling of the layer and distortion of the layer.

The intrinsic semiconductor layer and the semiconductor doped with the impurity are etched so as to form a semiconductor stripe 151 having a projection 154.

Subsequently, a conductor layer is formed on the substrate 110 by using a sputtering method and is then subjected to photolithography to form a plurality of data lines 171 including source electrodes 173 and end portions 179, drain electrodes 175, and isolated metal pieces 178.

A passivation layer 180p is formed on the data lines 171, the drain electrodes 175, and the isolated metal pieces 178, and color filters 230R and 230B are formed on the passivation layer 180p. Subsequently, a capping layer 180q is formed on the color filters 230R and 230B and a conductor layer made of ITO or IZO is deposited on the capping layer 180q and then subjected to photolithography to form a pixel electrode 191 having a central cutout 91, a lower cutout 92a, and an upper cutout 92b, an overpass 83, and a plurality of contact assistants 81 and 82. Then, an alignment layer 11 is coated thereon.

A manufacturing method of the common electrode panel 200 will now be described.

A light blocking member 220 is formed on the substrate 210. A transparent conductor layer made of ITO is formed on the light blocking member 220 and subjected to photolithography to form a common electrode having a plurality of cutout sets 71, 72a, and 72b, and an alignment layer 21 is coated over the common electrode 270.

Then, the TFT array panel 100 and the common electrode panel 200 are assembled and a liquid crystal material 310 is inserted between the panels 100 and 200.

An LCD according to another exemplary embodiment of the present invention will be described with reference to FIG. 1 to FIG. 3 and FIG. 5.

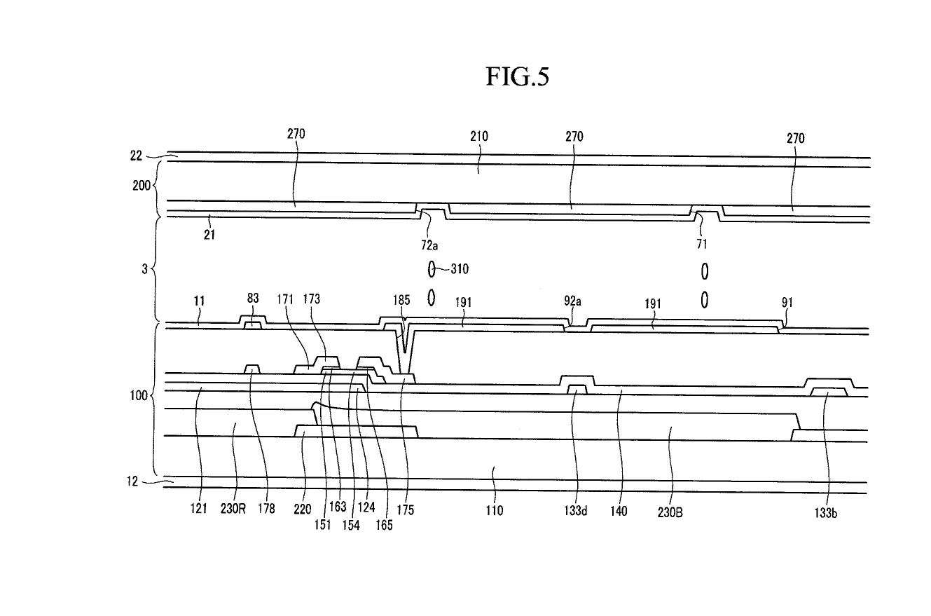

FIG. 5 is a cross-sectional view of the LCD of FIG. 3 according to another exemplary embodiment of the present invention, taken along line IV-IV.

Referring to FIG. 1 to FIG. 3 and FIG. 5, the LCD includes a TFT array panel 100, a common electrode display panel 200, and a liquid crystal layer 3 interposed between the two panels 100 and 200. The TFT array panel 100 and the common electrode display panel 200 face each other.

First, the TFT array panel 100 will be described with reference to FIG. 1, FIG. 3, and FIG. 5. Descriptions of the same elements will be omitted.

An insulating substrate 110 is made of soda lime glass containing an alkali component such as Na₂O, CaO, and MgO. As in the previous embodiment, the insulating substrate 110 has a surface waviness of less than about 0.06 μm and a surface roughness of less than about 20 Å.

A light blocking member 220 is formed on the insulating substrate 110 that is made of the soda lime glass. The light blocking member 220 is also called a black matrix, and it prevents light leakage from between the pixel electrodes and prevents light from a backlight from entering the semiconductor 151.

On the light blocking member 220, color filters 230R and 230B are formed. Herein, the color filter 230R refers to a red filter and the color filter 230B refers to a blue filter. The color filters 230R and 230B are alternately formed on pixel rows, and may be partially overlapped on the light blocking member 220.

A planarization layer 115 is formed on the color filters 230R and 230B. The planarization layer 115 may planarize surfaces of the color filter 230R and 230B.

The color filters 230R and 230B and the planarization layer 115 can prevent the alkali component eluted from the insulating substrate 110 that is made of the soda lime glass from moving toward elements.

On the planarization layer 115, a plurality of gate lines 121 including gate electrodes 124 and end portions 129 and a plurality of storage electrode lines 131 including a plurality of first, second, third, and fourth storage electrode sets 133a, 133b, 133c, and 133d and plurality of connections 133e are formed.

A gate insulating layer 140 is formed on the gate lines 121 and the storage electrode lines 131, and a plurality of semiconductor stripes 151, each having a projection 154, are formed on the gate insulating layer 140.

On the semiconductor stripes 151, a plurality of ohmic contact stripes (not shown) having a projection (163), and a plurality of ohmic contact islands 165 are formed. A pair of a projection of each ohmic contact 163 and 165 is disposed on each projection 154 of the semiconductor stripes 151.

A plurality of data lines including source electrodes 173 and end portions 179, a plurality of drain electrodes 175, and a plurality of isolated metal pieces 178 are formed on the ohmic contacts 163 and 165 and the gate insulating layer 140.

A passivation layer 180 is formed on the data lines 171, the drain electrodes 175, and isolated metal pieces 178, and exposed portions of the semiconductors 151. The passivation layer 180 may be made of an inorganic material, such as silicon nitride or silicon oxide.

On the passivation layer 180, a plurality of pixel electrode 191, a plurality of overpasses 83, and a plurality of contact assistants 81 and 82 are formed. Each pixel electrode 191 is physically and electrically connected to the drain electrode 175 through a contact hole 185 and receives a data voltage from the drain electrode 175.

Each pixel electrode 191 may have a quadrangle shape including four chamfered corners, and the chamfered sides of the pixel electrode 191 make an angle of about 45 degrees with the gate lines 121. A central cutout 91, a lower cutout 92a, and an upper cutout 92b are formed on each pixel electrode 191, and the pixel electrode 191 is divided into a plurality of partitions by these cutouts 91 to 92b.

Next, the common electrode panel 200 will be described with reference to FIG. 2, FIG. 3, and FIG. 5.

The insulating substrate 210 is made of soda lime glass containing an alkali component such as Na₂O, CaO, and MgO. As described above, the insulating substrate 210 has a surface waviness of less than 0.06 μm and a surface roughness of less than 20 Å.

A common electrode 270 having a plurality of cutout sets 71, 72a, 72b is formed on the insulating substrate 210 that is made of the soda lime glass.

Alignment layers 11 and 21 are coated on an inner surface of the display panels 100 and 200, and polarizers 12 and 22 are provided on an outer surface of the display panels 100 and 200.

An LCD according to another exemplary embodiment of the present invention will be described with reference to FIG. 1 to FIG. 3 and FIG. 6.

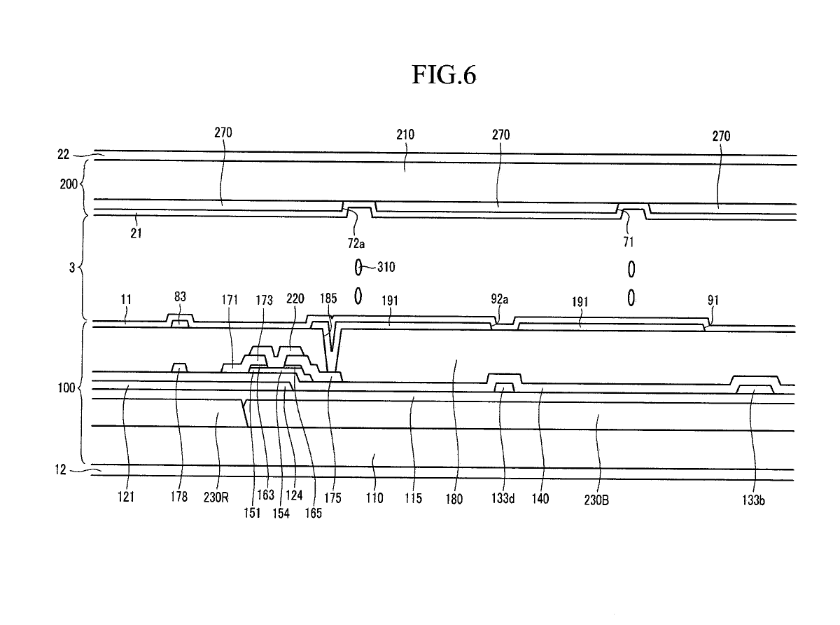

FIG. 6 is a cross-sectional view of the LCD of FIG. 3 according to another exemplary embodiment of the present invention, taken along line IV-IV.

A TFT array panel 100 will be described first with reference to FIG. 1, FIG. 3, and FIG. 6. Descriptions of the same elements will be omitted.

As previously described, an insulating substrate 110 is made of soda lime glass containing an alkali component such as Na₂O, CaO, and MgO. As previously described, the insulating substrate 110 has a surface waviness of less than about 0.06 μm and a surface roughness of less than about 20 Å.

Color filters 230R and 230B are formed on the insulating substrate 110 made of the soda lime glass. Unlike the above-described embodiment, the light blocking member 220 is not formed on the display panel 110 in the present embodiment.

A planarization layer 115 is formed on the color filters 230R and 230B. The planarization layer 115 may planarize surfaces of the color filters 230R and 230B.

The color filters 230R and 230B and the planarization layer 115 can prevent an inflow of an alkali material output from the insulating substrate 110 made of the soda lime glass to elements.

On the planarization layer 115, a plurality of gate lines 121 including gate electrodes 124 and end portions 129, and a plurality of storage electrode lines 131 including a plurality of first, second, third, and fourth storage electrode sets 133a, 133b, 133c, and 133d and a plurality of connections 133e are formed.

A gate insulating layer 140 is formed on the gate lines 121 and the storage electrode lines 131, and a plurality of semiconductors 151, each including a projection 154, are formed on the gate insulating layer 140.

On the semiconductor stripe 151, a plurality of ohmic contact stripes 163, each having a projection (not shown), and a plurality of ohmic contact islands 165 are formed.

On the ohmic contacts 163 and 165 and a gate insulating layer 140, a plurality of data lines 171 including source electrodes 173 and end portions 179, a plurality of drain electrodes 175, and a plurality of isolated metal pieces 178 are formed.

A light blocking member 220 is formed on the source electrode 173, the drain electrode 175, and a projection 154 of a semiconductor 151, exposed between the source electrode 173 and the drain electrode 175. The light blocking member 220 prevents external light from flowing into the semiconductor 151.

A passivation layer 180 is formed on the data lines 171, the drain electrodes 175, the isolated metal pieces 178, and the exposed portion of the semiconductor 151.

On the passivation layer 180, a plurality of pixel electrodes 191, a plurality of overpasses 83, and a plurality of contact assistants 81 and 82 are formed.

A common electrode panel 200 will be described with reference to FIG. 2, FIG. 3, and FIG. 6.

An insulating substrate 210 made of soda lime glass contains an alkali component such as Na₂O, CaO, and MgO. As previously described, the insulating substrate 210 has a surface waviness of less than 0.06 μm and a surface roughness of less than 20 Å.

On the insulating substrate 210 made of the soda lime glass, a common electrode 270 having a plurality of cutout sets 71, 72a, and 72b is formed.

Alignment layers 11 and 21 are coated in an inner surface of the display panels 100 and 200, and polarizers 12 and 22 are provided in an outer surface of the display panels 100 and 200.

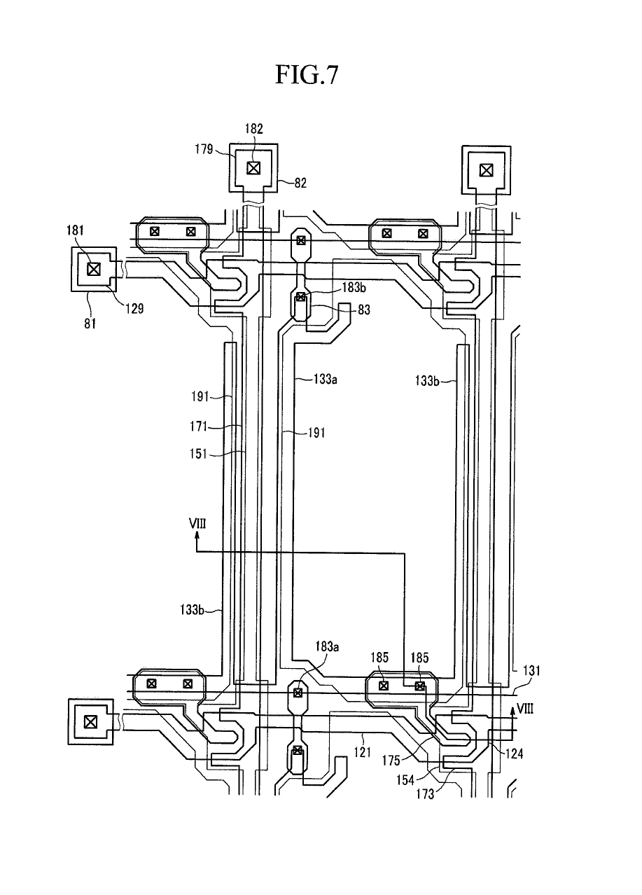

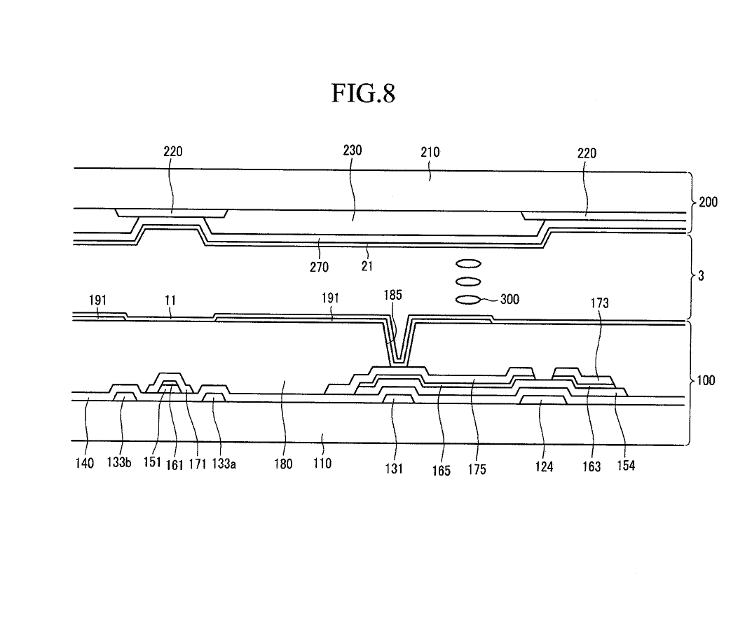

An LCD according to another exemplary embodiment of the present invention will be described with reference to FIG. 7 and FIG. 8.

FIG. 7 is a layout view of an LCD according to another exemplary embodiment of the present invention, and FIG. 8 is a cross-sectional view of the LCD of FIG. 7, taken along line VIII-VIII.

In the above-described exemplary embodiments, long axes of liquid crystal molecules are vertically aligned to the surfaces of the two display panels 100 and 200 in the state that an electric field is not generated in the vertically aligned LCD. However, the present exemplary embodiment will describe a horizontally aligned LCD having long axes of liquid crystal molecules that are parallel to the surfaces of the two display panels.

Similar to the previously-described exemplary embodiment, the LCD according to the present exemplary embodiment includes a TFT array panel 100, a common electrode panel 200, and a liquid crystal layer 3 interposed therebetween.

The TFT array panel 100 has the following structure.

On a soda lime glass substrate having a surface waviness of less that about 0.06 μm and a surface roughness of less than about 20 Å, a plurality of gate lines 121 including gate electrodes 124 and end portions 129 and a plurality of storage electrode lines 131 including storage electrodes 133a and 133b are formed. A gate insulating layer 140 is formed on the gate lines 121 and the storage electrode lines 131, and a plurality of semiconductor stripes 151 including projections 154 that are protruded toward the gate electrodes 124 are formed on the gate insulating layer 140. On the semiconductor stripes 151, a plurality of data lines 171 including source electrodes 173 and end portions 179 and a plurality of drain electrodes 175 are formed. Between the semiconductor stripes 151 and the data lines 171 and between the semiconductor stripes 151 and the drain electrodes 175, ohmic contacts 161, 163, and 165 are formed. A passivation layer 180 having a plurality of contact holes 181, 182, 183a, 183b, and 185 is formed on the data lines 171 and the drain electrodes 175, and a plurality of pixel electrodes 191 and a plurality of contact assistants 81 and 82 are formed on the passivation layer 180. Unlike the previously-described exemplary embodiments, the pixel electrodes 191 do not have a cutout.

The common electrode panel 200 has the following structure.

On a soda lime glass substrate 210 having a surface waviness of less than about 0.06 μm and a surface roughness of less than about 20 Å, a light blocking member 220 having a plurality of openings is formed and a color filter 230 is formed on the openings and light blocking member 220. The common electrode 270 is formed on the light blocking member 220 and the color filter 230, and, unlike the previously-described exemplary embodiments, the common electrode 270 does not have a cutout.

Alignment layers 11 and 12 are coated on an inner side of the display panel 100 and 200.

The liquid crystal layer 3 is in a state of positive dielectric anisotropy, and liquid crystal molecules 310 in the liquid crystal layer 2 are aligned such that their long axes are almost parallel to the surfaces of the display panels 100 and 200 when no electric field is generated. While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A display panel comprising:
an alkali-containing glass substrate having a surface waviness of less than about 0.06 μm;
a gate electrode formed on the substrate;
a gate insulating layer formed on the gate electrode;
a semiconductor formed on the gate insulating layer;
a source electrode and a drain electrode that contact the semiconductor; and
a pixel electrode electrically connected to the drain electrode.

2. The display panel of claim 1, wherein the alkali-containing glass substrate has a surface roughness of less than about 20 Å.

3. The display panel of claim 1, wherein the gate insulating layer includes silicon nitride (SiNx), and has a thickness between about 500 Å to about 4500 Å.

4. The display panel of claim 3, wherein the gate insulating layer includes a first gate insulating layer and a second gate insulating layer, each having a different deposition density.

5. The display panel of an of claim 1 to claim 4, wherein the alkali-containing glass substrate is a soda lime glass substrate.

6. A display panel comprising:
an alkali-containing glass substrate having a surface waviness of less than about 0.06 μm;
a gate electrode formed on the substrate;
a gate insulating layer formed on the gate electrode;
a semiconductor formed on the gate insulating layer;
a source electrode and a drain electrode that contact the semiconductor;
a pixel electrode connected to the drain electrode and including a plurality of cutouts; and
a color filter disposed between the substrate and the pixel electrode.

7. The display panel of claim 6, wherein the color filter is disposed between the source electrode, the drain electrode, and the pixel electrode, and the display panel further comprises an inorganic insulating layer interposed between the color filter and the pixel electrode.

8. The display panel of claim 6, wherein the color filter is disposed between the substrate and the gate electrode, and the display panel further comprises a planarization layer interposed between the color filter and the gate electrode.

9. The display panel of claim 8, further comprising a light blocking member disposed in a lower portion of the color filter.

10. The display panel of claim 8, further comprising a light blocking member disposed in an upper portion of the semiconductor.

11. The display panel of any of claim 6 to claim 10, wherein the alkali-containing glass substrate is a soda lime glass substrate.

12. A manufacturing method of a display panel, the manufacturing method comprising:
preparing an alkali-containing glass substrate having a surface waviness of less than about 0.06 μm;
forming a gate electrode on the substrate;
substantially forming a gate insulating layer and a semiconductor on the gate electrode;
forming a source electrode and a drain electrode on the gate insulating layer and the semiconductor; and
forming a pixel electrode connected to the drain electrode.

13. The manufacturing method of claim 12, wherein the preparing of the alkali-containing glass substrate comprises polishing a surface of the substrate.

14. The manufacturing method of claim 12, wherein the preparing of the alkali-containing glass substrate comprises forming a planarization layer on the substrate.

15. The manufacturing method of claim 12, wherein the gate insulating layer and the semiconductor are formed by deposition at a temperature of less than about 250° C.

16. The manufacturing method of claim 15, wherein the forming of the gate insulating layer comprises:
forming a first gate insulating layer; and
forming a second gate insulating layer with a deposition condition that is different from a deposition condition of the first gate insulating layer to make the first gate insulating layer and the second gate insulating layer have different densities.

17. The manufacturing method of claim 12, further comprising performing an annealing process on the substrate before the preparing of the alkali-containing glass substrate.

18. The manufacturing method of claim 17, wherein the annealing process is performed on the substrate by using a convection oven at a temperature between about 150 and about 400° C.

19. The manufacturing method of claim 17, wherein the annealing process is performed by placing the substrate in a furnace.

20. The manufacturing method of claim 19, wherein an annealing temperature of the substrate is about 400 to about 500° C.

21. The manufacturing method of claim 12, further comprising, before the forming of the pixel electrode:
forming a color filter after forming the source electrode and the drain electrode; and
forming an inorganic insulating layer on the color filter.

22. The manufacturing method of claim 12, further comprising, before the forming of the gate electrode:
forming a color filter on the substrate; and
forming a planarization layer on the color filter.

23. A manufacturing method of a display panel, the manufacturing method comprising:
performing an annealing process on an alkali-containing glass substrate;
polishing the alkali-containing glass substrate on the substrate to make a surface waviness of the substrate less than about 0.06 μm;
forming a gate electrode on the substrate;
substantially forming a gate insulating layer and a semiconductor at a temperature of less than about 250° C. after forming the gate electrode;
forming a source electrode and a drain electrode after forming the gate insulating layer and the semiconductor; and
forming a pixel electrode connected to the drain electrode.

24. A manufacturing method of a display panel, the manufacturing method comprising:
performing an annealing process on an alkali-containing glass substrate;
forming a planarization layer to make a surface waviness of the substrate less than about 0.06 μm;
forming a gate electrode on the substrate;
substantially forming a gate insulating layer and a semiconductor at a temperature of less than about 250° C. after forming the gate electrode;
forming a source electrode and a drain electrode after forming the gate insulating layer and the semiconductor; and
forming a pixel electrode connected to the drain electrode.

25. The manufacturing method of claim 23 or claim 24, wherein the forming of the gate insulating layer comprises:
forming a first gate insulating layer; and
forming a second gate insulating layer with a deposition condition that is different from a deposition condition of the first gate insulating layer to make the first gate insulating layer and the second gate insulating layer have different densities.

26. The manufacturing method of claim 23 or claim 24, wherein the annealing process is performed on the substrate by using a convection oven at a temperature between about 150 and about 400° C.

27. The manufacturing method of claim 23 or claim 24, wherein the annealing process is performed on the substrate placed in a furnace.

28. The manufacturing method of claim 27, wherein an annealing temperature of the substrate is about 400 to about 500° C.

29. The manufacturing method of claim 23 or claim 24, further comprising, before the forming of the pixel electrode:
forming a color filter after forming the source electrode and the drain electrode; and
forming an inorganic insulating layer on the color filter.

30. The manufacturing method of claim 23 or claim 24, further comprising, before the forming of the gate electrode:
forming a color filter on the substrate; and
forming a planarization layer on the color filter.
